(19) United States
(12) Patent Application Publication
(10) Pub. No.: US 2013/0016559 A1
(43) Pub. Date: Jan. 17, 2013

(54) NAND FLASH MEMORY SYSTEM AND METHOD PROVIDING REDUCED POWER CONSUMPTION

(71) Applicants: JONG-UK SONG, SEOUL (KR); SOON-BOK JANG, SEOUL (KR); YOUNG-WOOK KIM, GUNPO-SI (KR); HYUN-JIN KIM, SUWON-SI (KR)

(72) Inventors: JONG-UK SONG, SEOUL (KR); SOON-BOK JANG, SEOUL (KR); YOUNG-WOOK KIM, GUNPO-SI (KR); HYUN-JIN KIM, SUWON-SI (KR)

(73) Assignee: SAMSUNG ELECTRONICS CO., LTD., SUWON-SI (KR)

(21) Appl. No.: 13/547,435

(22) Filed: Jul. 12, 2012

(30) Foreign Application Priority Data
Jul. 12, 2011 (KR) 10-2011-0068791

(51) Int. Cl. G11C 16/04

(52) U.S. Cl. 365/185.05; 365/185.18

(57) ABSTRACT

A NAND flash memory device comprises a NAND flash memory comprising a first pad and a plurality of second pads. The first pad comprises a first receiver configured to receive a first signal. The second pads comprise a plurality of respective second receivers configured to receive a plurality of respective second signals. The second receivers are selectively powered, i.e., turned on or off, according to a logic level of the first signal.

### CROSS-REFERENCE TO RELATED APPLICATIONS

This application claims priority under 35 U.S.C. §119 to Korean Patent Application No. 10-2011-0068971 filed on Jul. 12, 2011, the subject matter of which is hereby incorporated by reference.

### BACKGROUND OF THE INVENTION

The inventive concept relates generally to electronic memory technologies. More particularly, the inventive concept relates to a NAND flash memory system and method providing reduced power consumption.

NAND flash memory devices can be found in a wide variety of technical applications, such as digital cameras, cellular phones, flash memory drives, and personal computers (PCs), to name but a few. For many of these applications, power consumption is a significant concern, perhaps due to limited battery life, cost, heat, or other factors. Accordingly, there is a general need to limit the power consumption by memory devices and other components.

As NAND flash memory devices become increasingly integrated, their power consumption tends to increase. Consequently, researchers are constantly seeking ways to limit this power consumption. One source of unnecessary power consumption in NAND flash memory devices is interface pads. These components may consume power unnecessarily even when the NAND flash memory device is not performing significant communication.

### SUMMARY OF THE INVENTION

In one embodiment of the inventive concept, a NAND flash memory device comprises a NAND flash memory. The NAND flash memory device comprises a first pad comprising a first receiver configured to receive a first signal, and a plurality of second pads comprising a plurality of respective second receivers configured to receive a plurality of respective second signals. The second receivers are selectively powered according to a logic level of the first signal.

In another embodiment of the inventive concept, a NAND flash memory system comprises a NAND flash memory comprising a plurality of first pads, and a controller configured to control the NAND flash memory and comprising a plurality of second pads. Each of the first pads comprises a receiver, and each of the plurality of second pads comprises a driver. Each receiver receives one signal among a first signal and a plurality of second signals. Each driver transmits one signal among the first signal and the plurality of second signals. Power of receivers that receive the second signals and power of drivers that transmit the second signals are controlled in response to the first signal.

In another embodiment of the inventive concept, a method of operating a NAND flash memory system comprises transmitting signals between a plurality of drivers in pads of a controller to a plurality of corresponding receivers in pads of a NAND flash memory device, and selectively powering up or down a plurality of the receivers in response to a logic level of a first signal applied to one of the receivers.

These and other embodiments of the inventive concept can potentially reduce the power consumption of systems incorporating NAND flash memory devices.

### BRIEF DESCRIPTION OF THE DRAWINGS

The drawings illustrate selected embodiments of the inventive concept. In the drawings, like reference numbers indicate like features.

FIG. 1A is a block diagram of a memory system according to an embodiment of the inventive concept.

FIG. 1B illustrates communication between a pad of a controller and a pad of a NAND flash memory in the memory system illustrated in FIG. 1A.

FIG. 2 is a block diagram illustrating core logic and pads of the controller of the memory system illustrated in FIG. 1A.

FIG. 3 is a block diagram illustrating an example of core logic and pads of the NAND flash memory in the memory system illustrated in FIG. 1A.

FIG. 4 illustrates a state of a receiver when a chip enable signal is at a first logic level in the memory system illustrated in FIG. 1A.

FIG. 5 illustrates a state of pads that receive the chip enable signal according to various signals of the memory system illustrated in FIG. 1A.

FIG. 6 illustrates a state of a receiver when a chip enable signal or a first signal is at a first logic level in the memory system illustrated in FIG. 1A.

FIG. 7 illustrates a state of pads that receive various signals according to the chip enable signal in the memory system illustrated in FIG. 1A.

FIG. 8 illustrates a state of a driver and a state of a receiver when a chip enable signal or a first signal is at a first logic level in the memory system illustrated in FIG. 1A.

FIG. 9 illustrates a state of pads that receive various signals according to the chip enable signal in the memory system illustrated in FIG. 1A.

FIG. 10 illustrates a state of a driver and a state of a receiver when the level of a chip enable signal or a first signal is changed to a second logical level from a first logic level in the memory system illustrated in FIG. 1A.

FIG. 11 illustrates a state of pads that receive various signals according to the chip enable signal illustrated in FIG. 10 in the memory system illustrated in FIG. 1A.

FIG. 12 illustrates a plurality of NAND flash memories connected to one controller according to an embodiment of the inventive concept.

FIG. 13 illustrates a NAND flash memory system according to an embodiment of the inventive concept.

FIG. 14 is a block diagram of a computing system according to an embodiment of the inventive concept.

FIG. 15 is a flowchart illustrating a method of operating a NAND flash memory according to an embodiment of the inventive concept.

### DETAILED DESCRIPTION

Embodiments of the inventive concept are described below with reference to the accompanying drawings. These embodiments are presented as teaching examples and should not be construed to limit the scope of the inventive concept.

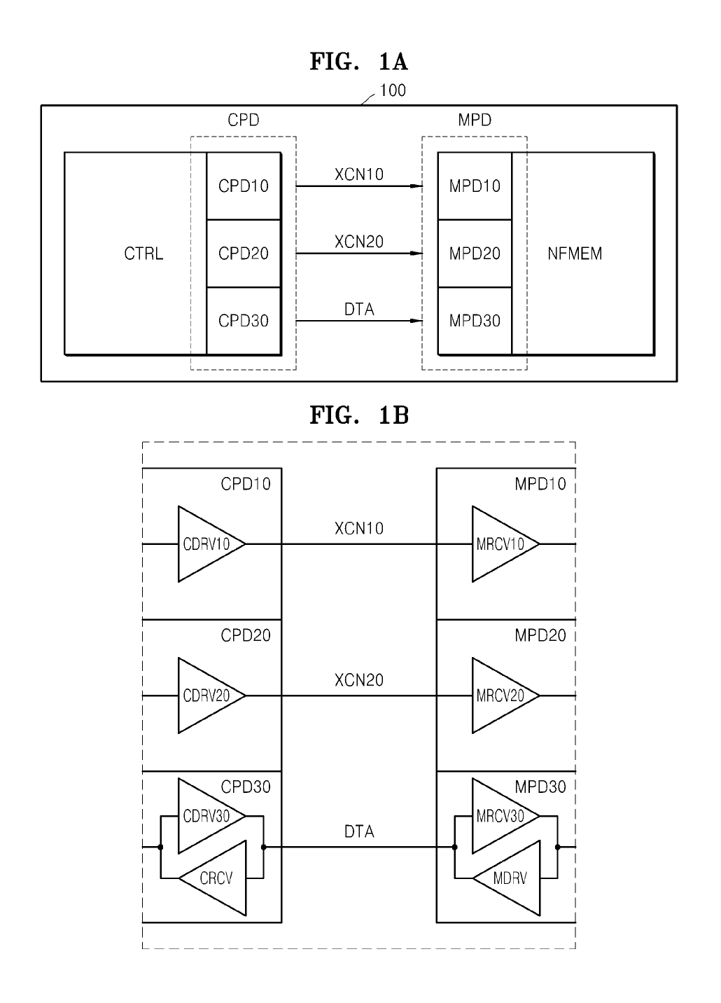

FIG. 1A is a block diagram of a memory system 100 according to an embodiment of the inventive concept.

Referring to FIG. 1A, memory system 100 comprises a NAND flash memory NFMEM and a controller CTRL that controls NAND flash memory NFMEM. Memory system 100 performs communication between NAND flash memory NFMEM and controller CTRL using signals XCN10, XCN20, and a data signal DTA. Control signal XCN10 is referred to as a first signal, and it may comprise a chip enable (CE) signal. In addition, control signal XCN20 and data signal DTA are referred to as second signals.

The communication is performed between a pad CPD of controller CTRL and a pad MPD of NAND flash memory NFMEM. Moreover, the communication can be expressed as being performed between drivers and receivers that are disposed inside pads CPD and MPD. Pad CPD comprises a pad CPD10, a pad CPD20, and a pad CPD30. Pad MPD of NAND flash memory NFMEM comprises a pad MPD10, a pad MPD20, and a pad MPD30.

As illustrated in FIG. 1B, pad CPD and pad MPD comprise, collectively, drivers CDRV10 and CDRV20, receivers MRCV10 and MRCV20, and drivers CDRV30 and MDRV and receivers CRCV and MRCV30. These drivers and receivers are used to receive and transmit signals. Power for driving the drivers and the receivers is supplied to memory system 100 in order to perform communication.

Referring to FIG. 1A, one of control signals XCN10 and XCN20 that is transmitted to NAND flash memory NFMEM from controller CTRL is the CE signal. The CE signal is transmitted to pad MPD of NAND flash memory NFMEM. A bus between controller CTRL and NAND flash memory NFMEM is enabled in response to the CE signal to allow communication.

FIG. 1B illustrates communication between pad CPD of controller CTRL and pad MPD of NAND flash memory NFMEM of memory system 100 illustrated in FIG. 1A.

Referring to FIG. 1B, receiver MRCV10, which receives the CE signal, is turned on when memory system 100 is turned on. The CE signal is continuously received from receiver MRCV10. Where the CE signal is at a first logic level, receiver MRCV20 is turned off. Thus, even where a signal is input to pad MPD20, the signal is not transmitted to NAND flash memory NFMEM. Where the CE signal transitions from the first logic level to a second logic level, receiver MRCV20 of pad MPD20 is turned on. A more detailed description of these and other operations of receiver MRCV20 will be provided below.

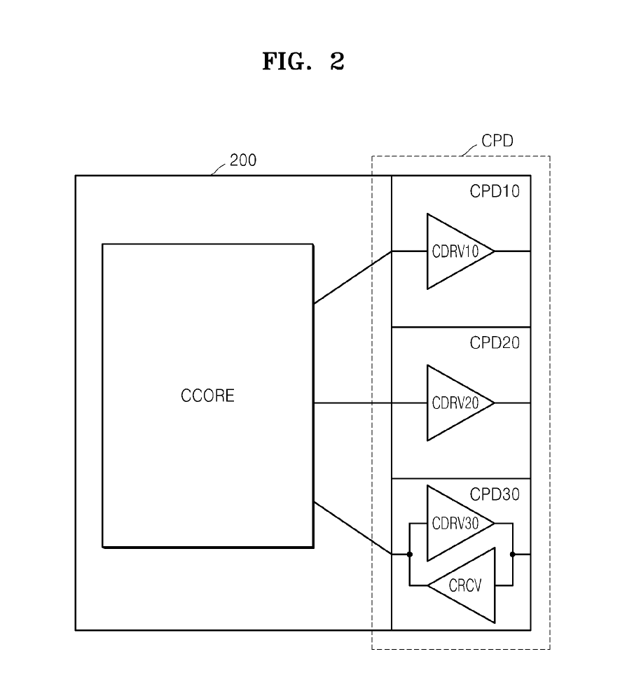

FIG. 2 is a block diagram of core logic CCORE of controller CTRL and pads CPD10, CPD20, and CPD30 of controller CTRL in memory system 100.

Referring to FIG. 2, signals processed by core logic CCORE of controller CTRL are transmitted to NAND flash memory NFMEM via pads CPD10, CPD20, and CPD30. Pad CPD10 is used for communicating the CE signal. Pad CPD20 is used for communicating at least one signal among an address enable (ADE) signal, a common enable (COE) signal, a ready/busy (RB) signal, a read enable (RE) signal, a write enable (WE) signal, and a write protect (WP) signal. Pad CPD30 is used for communicating at least one of a data (DQ) signal and a data synch (DQS) signal. In addition, pads CPD10 and CPD20 may not comprise receivers, or even where they do comprise receivers, the receivers may be turned off.

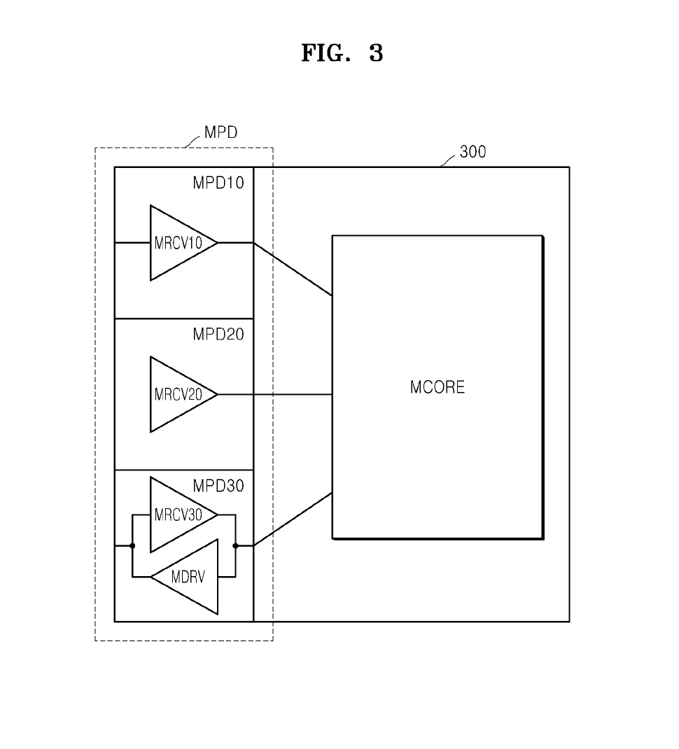

FIG. 3 is a block diagram of core logic MCORE of NAND flash memory NFMEM and pads MPD10, MPD20, and MPD30 of NAND flash memory NFMEM in memory system 100.

Referring to FIG. 3, NAND flash memory NFMEM receives signals transmitted from controller CTRL from pads MPD10, MPD20, and MPD30. Pad MPD10 is used for communicating the CE signal. Pad MPD20 is used for communicating at least one signal among an ADE signal, a COE signal, an RB signal, an RE signal, a WE signal, and a WP signal. Pad MPD30 is used for communicating at least one of a DQ signal and a DQS signal.

The signals shown in FIGS. 2 and 3 are examples, and the inventive concept is not limited to specific types, names, or number of signals. In addition, the inventive concept is not limited a specific number of pads, drivers, or receivers illustrated in FIGS. 2 and 3. Each of pads MPD10, MPD20, and MPD30 is used for communicating one signal, as in FIG. 2. In addition, pads MPD10 and MPD20 may not comprise drivers, or they may have drivers that are turned off. Pads illustrated in FIGS. 5, 7, 9, and 11 comprise drivers and/or receivers such as those illustrated in FIGS. 2 and 3.

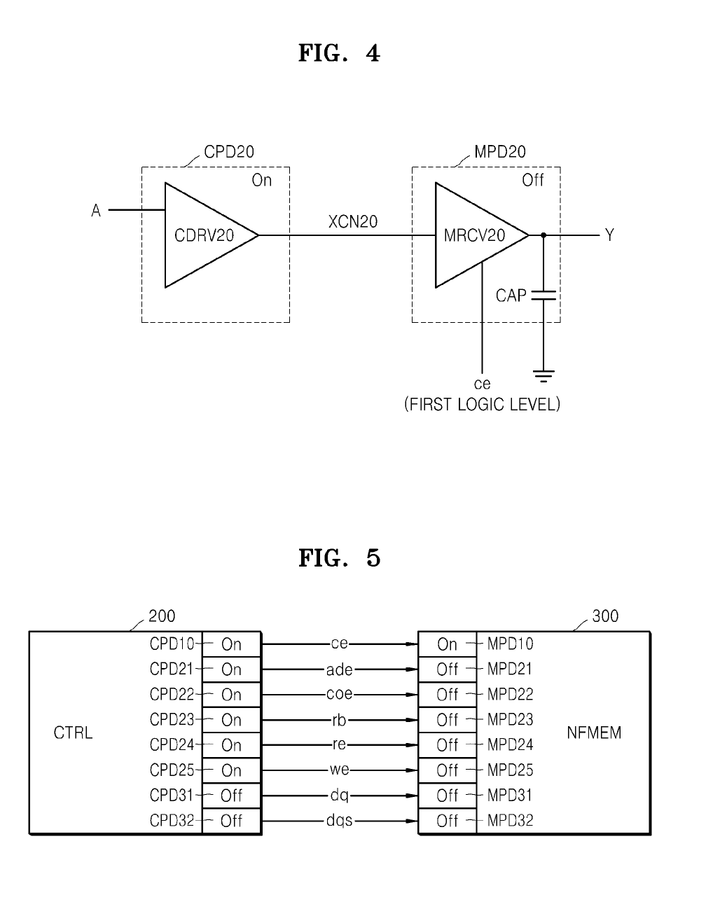

FIG. 4 illustrates a state of receiver MRCV20 where the CE signal or the first signal is at a first logic level (e.g., at a high level) in memory system 100. FIG. 5 illustrates states of pads (or a state of at least one of drivers and receivers in the pads) that receive the CE signal, according to various signals of memory system 100.

Referring to FIG. 4, a signal A is a control signal input to pad CPD20 from core logic CCORE, and driver CDRV20 is turned on. Receiver MRCV20 of pad MPD20 may be a three-phase buffer, for example. In this case, a signal output from receiver MRCV20 is generated according to the CE signal. A control signal XCN20 of receiver MRCV20 is input to pad CPD20, and receiver MRCV20 is turned off. Because receiver MRCV20 is turned off, an output (Y) signal is not generated. Thus, signal A is not transmitted to core logic MCORE of controller CTRL. This configuration may be used, for instance, where signal A is data signal DTA.

Referring to FIG. 5, pad CPD20 of FIG. 2 comprises a plurality of pads including a pad CPD21, a pad CPD22, a pad CPD23, a pad CPD24, and a pad CPD25. The term “pad CPD20” may refer to more than one pad. Pad MPD20 comprises a plurality of pads including a pad MPD21, a pad MPD22, a pad MPD23, a pad MPD24, and a pad MPD25. Accordingly, the term “pad MPD20” may refer to more than one pad. Similarly, pad CPD30 may comprise a pad CPD31 and a pad CPD32, and the term “pad CPD30” may refer to more than one pad. Likewise, pad MPD30 may comprise a pad MPD31 and a pad MPD32, and the term “pad MPD30” may refer to more than one pad. This terminology may also be applied to the description of FIGS. 7, 9, and 11, for example.

Referring to FIGS. 4 and 5, where the CE signal is at the first logic level, receiver MRCV20 is turned off. For example, in FIG. 5, receivers of pads MPD21, MPD22, MPD23, MPD24, and MPD25 are turned off. As s a result, drivers CDRV30 and MDRV and receivers CRCV and MRCV30 are turned off. For example, in FIG. 5, drivers and receivers of pads CPD31 and CPD32 and pads MPD31 and MPD32 are turned off.

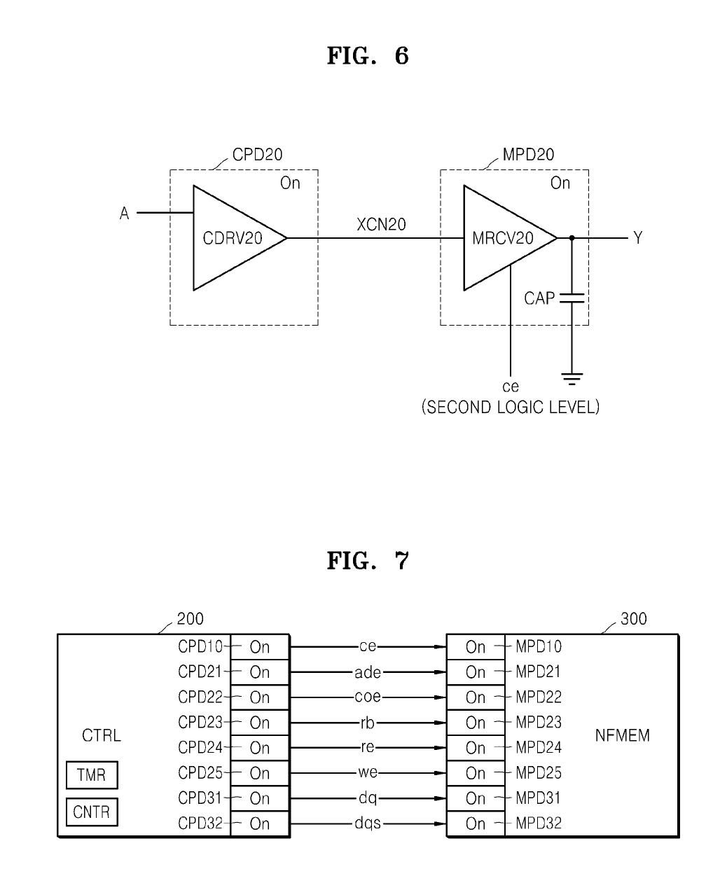

FIG. 6 illustrates a state of receiver MRCV20 after the CE signal or the first signal transitions from the first logic level (e.g., a high level) to the second logic level (e.g., a low level) in memory system 100. FIG. 7 illustrates states of pads (or receivers, drivers, or receivers and drivers in the pads) that receive the CE signal illustrated in FIG. 6 according to various signals of memory system 100.

Referring to FIG. 6, driver CDRV20 is turned on and the signal A is input to driver CDRV20. The signal A is a control signal. The signal XCN20 output from driver CDRV20 is an input signal of receiver MRCV20. Because receiver MRCV20 is turned on, it generates the output (Y) signal.

Referring to FIGS. 6 and 7, the CE signal is at the second logic level and receiver MRCV20 is turned on. Accordingly, in FIG. 7, all of the receivers of pads MPD21, MPD22, MPD23, MPD24, and MPD25 are turned on. This is because the level of the CE signal has been changed to the second logic level from the first logic level. In addition, drivers CDRV30 and MDRV and receivers CRCV and MRCV30 are turned on. Accordingly, in FIG. 7, all of the receivers and the drivers of pads CPD31 and CPD32 and pads MPD31 and MPD32 are turned on. Although FIGS. 6 and 7 illustrate an example where the receivers and drivers are turned on in response to a signal transitioning from a first logic level to a second logic level, these components could alternatively be turned on in response to a signal transitioning from the second logic level to a first logic level.

In another embodiment, where the state of receiver MRCV20 is changed to the turned-on state from the turned-off state, the NAND flash memory NFMEM may be simultaneously powered up. In still another embodiment, where receiver MRCV20 is changed to the turned-on state from the turned-off state, NAND flash memory NFMEM may be powered up after a predetermined amount of time elapses. In general, power of NAND flash memory NFMEM may be turned off while communication between pad CPD20 and pad MPD20 is not performed.

Where the state of the receiver or driver of the pad is changed to the turned-on state from the turned-off state, communication is not performed between pads CPD21 to CPD25, CPD31, and CPD32 and pads MPD21 to MPD25, MPD31, and MPD32. Where the state of the receiver or driver of the pad has been changed to the turned-on state from the turned-off state, communication between the pads CPD21 to CPD25, CPD31, and CPD32 and the pads MPD21 to MPD25, MPD31, and MPD32 is performed.

Where communication between the pads has been completed, the level of the CE signal is changed to the first logic level from the second logic level, and communication between pads CPD21 to CPD25, CPD31, and CPD32 and pads MPD21 to MPD25, MPD31, and MPD32 is not performed. Core logic CCORE determines whether communication between the pads has been completed or not.

In some embodiments, core logic CCORE determines through a timer TMR or a counter CNTR whether communication has been completed or not. For example, timer TMR may start to operate after communication between pad CPD21 and pad MPD21 has started, and core logic CCORE may determine that communication has completed after an elapsed time. Timer TMR may allow drivers or receivers of pads CPD30, MPD20, and MPD30 to be turned off by varying the CE signal or indirectly without varying the CE signal. In addition, counter CNTR may operate similar to timer TMR.

In some embodiments, completion of communication may be determined based on the voltage level of a capacitor CAP connected to the receiver, as illustrated in FIG. 6. For example, capacitor CAP may be connected in series to an output terminal of receiver MRCV20. Capacitor CAP may be charged or discharged and may indicate a time of completion for communication, similar to timer TMR.

NAND flash memory NFMEM may be powered down where the state of receiver MRCV20 is changed to the turned-off state from the turned-on state. Where memory system 100 of FIG. 1A has the function described above, the amount of power consumed by pad MPD20 and the amount of power used by NAND flash memory NFMEM may be reduced.

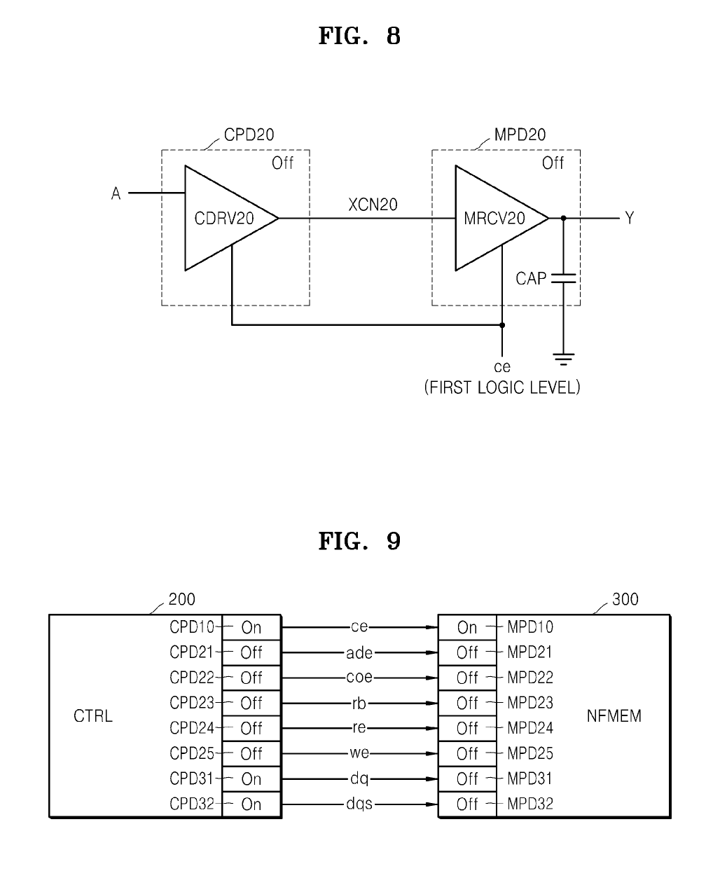

FIG. 8 illustrates a state of driver CDRV20 and a state of receiver MRCV20 where the CE signal or the first signal is at the first logic level (e.g., a high level) in memory system 100 illustrated in FIG. 1A. FIG. 9 illustrates states of pads (or the state of at least one of drivers and receivers in the pads) that receive the CE signal according to various signals of memory system 100.

Referring to FIG. 8, signal A is a control signal that is input to pad CPD20 from core logic CCORE of controller CTRL. Receiver MRCV20 and driver CDRV20 may be three-phase buffers, for example. In this case, signals are output from receiver MRCV20 and driver CDRV20 according to the CE signal. Input signal A is input to driver CDRV20, and an output thereof is not generated because driver CDRV20 is turned off. Because receiver MRCV20 is also turned off, the output (Y) signal is not generated. This configuration may be used, for instance, where signal A is data signal DTA.

Referring to FIGS. 8 and 9, driver CDRV20 is also controlled in response to the CE signal, unlike in FIGS. 4 and 5. Other operations of driver CDRV20 illustrated in FIGS. 8 and 9 are similar to those of FIGS. 4 and 5. In the embodiment of FIGS. 8 and 9, the amount of power used by the receiver and the amount of power used by the driver may also be reduced. Where the CE signal is at the first logic level, receiver MRCV20 and driver CDRV20 are turned off. For example, in FIG. 9, all receivers of the pads MPD21, MPD22, MPD23, MPD24, and MPD25 and all drivers of the pads CPD21, CPD22, CPD23, CPD24, and CPD25 are turned off. In this case, drivers CDRV30 and MDRV and receivers MRCV30 and CRCV are turned off. For example, in FIG. 9, the drivers and the receivers of pads CPD31 and CPD32 and pads MPD31 and MPD32 are turned off.

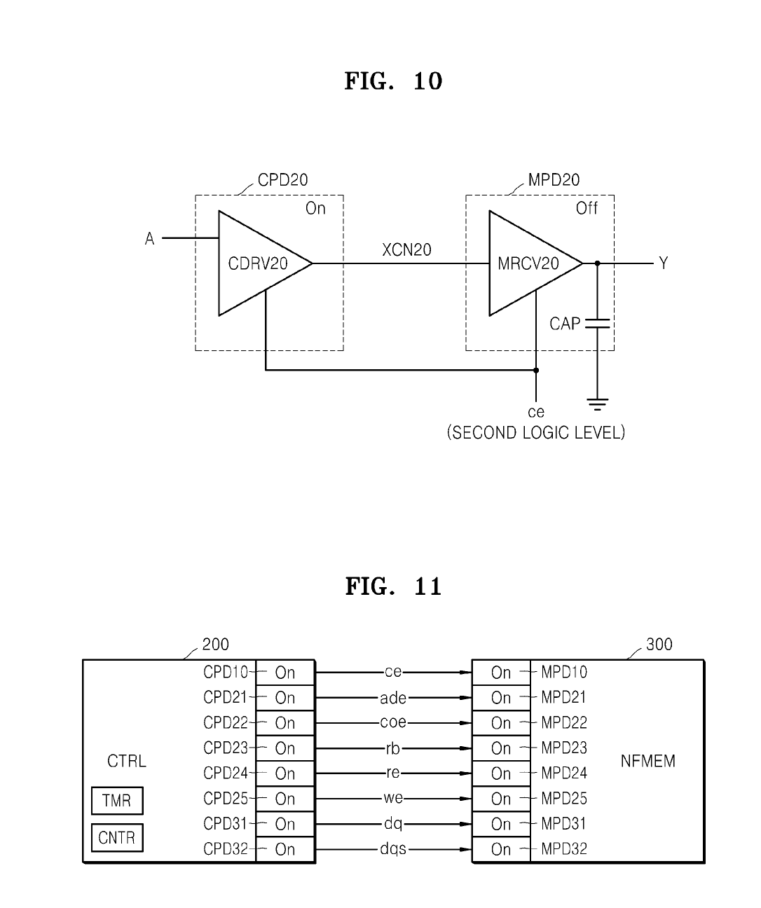

FIG. 10 illustrates a state of driver CDRV20 and a state of receiver MRCV20 where the level of the CE signal or the first signal is changed to the second logical level (e.g., a low level), from the first logic level (e.g., a high level) in memory system 100 illustrated in FIG. 1A. FIG. 11 illustrates states of pads (or the state of at least one of drivers and receivers in the pads) that receive the CE signal illustrated in FIG. 10 according to various signals of memory system 100.

Referring to FIG. 10, input signal A is input to driver CDRV20. Because driver CDRV20 is turned on, a signal output from driver CDRV20 is an input signal of receiver MRCV20. Because receiver MRCV20 is turned on, the output (Y) signal is generated.

Referring to FIGS. 10 and 11, the CE signal is at the second logic level, and receiver MRCV20 and driver CDRV20 are turned on. For example, in FIG. 11, all receivers of pads MPD21, MPD22, MPD23, MPD24, and MPD25 and all drivers of pads CPD21, CPD22, CPD23, CPD24, and CPD25 are turned on. This is because the CE signal has been changed to the second logic level from the first logic level. Accordingly, drivers CDRV30 and MDRV and receivers CRCV and MRCV30 are turned on.

In the example of FIG. 11, all receivers and drivers of pads CPD31 and CPD32 and pads MPD31 and MPD32 are turned on. However, the scheme for changing of the state of the receiver and the driver to the turned-on state from the turned-off state in FIG. 11 is merely an example, and the inventive concept is not limited thereto. For instance, the respective states of the driver and the receiver may be changed to the turned-on state from the turned-off state in response to a signal at the second logic level and another signal at the first logic level. Alternatively, by changing the driver and the receiver from the second logic level to the first logic level or from the first logic level to the second logic level, the state of the driver and the receiver may be changed to the turned-on state from the turned-off state.

In another embodiment, where the state of receiver MRCV20 is changed to the turned-on state from the turned-off state, NAND flash memory NFMEM may be simultaneously powered up. In another embodiment, where the state of receiver MRCV20 is changed to the turned-on state from the turned-off state, NAND flash memory NFMEM may be powered up after a predetermined amount of time elapses. NAND flash memory MFMEM is typically turned off where communication between pad CPD20 and pad MPD20 is not performed.

Referring still to FIGS. 10 and 11, where the state of the receiver or the driver of the pad is changed to the turned-on state from the turned-off state, communication between pads CPD21 to CPD25, CPD31, and CPD32 and pads MPD21 to MPD25, MPD31, and MPD32 is not performed. Where the state of the receiver or the driver of the pad is changed to the turned-on state from the turned-off state, communication between pads CPD21 to CPD25, CPD31, and CPD32 and pads MPD21 to MPD25, MPD31, and MPD32 is performed.

After the driver and the receiver are turned on, the driver and the receiver may be turned off in a manner similar to that described with reference to FIGS. 6 and 7. Where communication between the pads has been completed, the CE signal is changed to the first logic level from the second logic level, and communication between pads CPD21 to CPD25, CPD31, and CPD32 and pads MPD21 to MPD25, MPD31, and MPD32 is not performed. Under these conditions, core logic CCORE may determine whether communication has been completed.

In some embodiments, core logic CCORE determines whether communication has been completed based on a method using timer TMR or counter CNTR. For example, timer TMR may start to operate after communication between pad CPD21 and pad MPD21 has started. Timer TMR may allow drivers or receivers of the pads CPD30, MPD20, and MPD30 to be turned off by varying the CE signal or indirectly without varying the CE signal. Counter CNTR may operate similarly to timer TMR.

In another embodiment, whether communication has been completed may be determined from the voltage level of capacitor CAP connected to the receiver, as illustrated in FIG. 10. For example, capacitor CAP may be connected in series to an output terminal of receiver MRCV20. Capacitor CAP may be charged or discharged and may control the timing of the CE signal, similar to timer TMR.

NAND flash memory NFMEM may be powered down when the state of receiver MRCV20 is changed to the turned-off state from the turned-on state. Where memory system 100 of FIG. 1A has the function described above, the amount of power consumed by pad MPD20 and the amount of power used by NAND flash memory NFMEM may also be reduced.

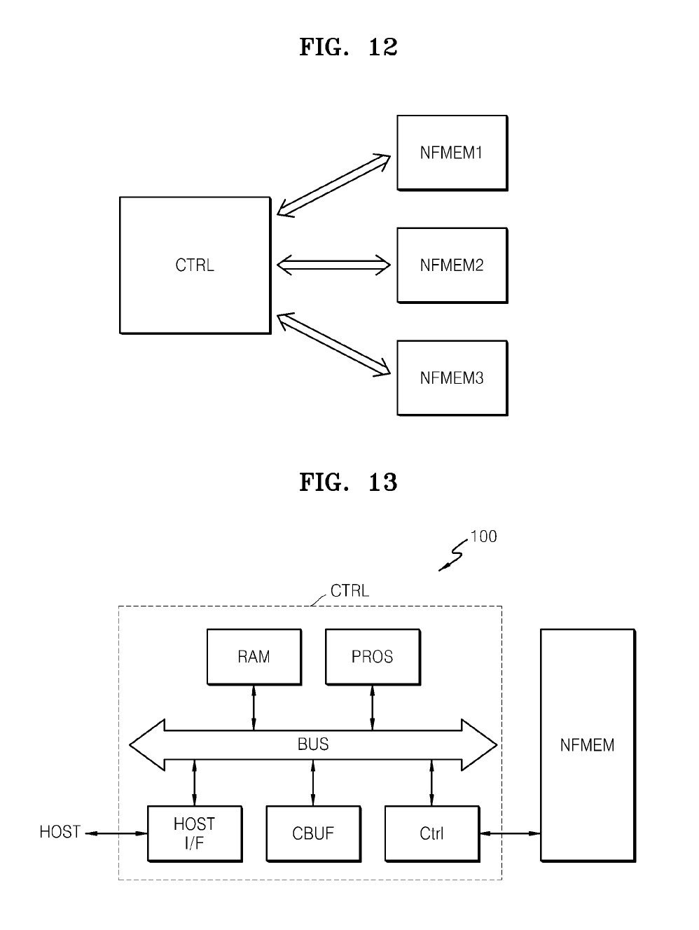

FIG. 12 illustrates a plurality of NAND flash memories NFMEM1 to NFMEM3 connected to one controller CTRL according to another embodiment of the inventive concept.

Referring to FIG. 12, communication between one controller CTRL and NAND flash memories NFMEM1 to NFMEM3 is performed according to a control signal and a data signal output from one controller CTRL. The control signal may comprise the first signal or the CE signal illustrated in FIGS. 1 through 11.

In some embodiments, the power of receivers in NAND flash memories NFMEM1 to NFMEM3 may be controlled according to the CE signal output from the single controller CTRL. In other embodiments, NAND flash memories NFMEM1 to NFMEM3 may be controlled according to the CE signal, as illustrated in FIGS. 4 through 7. In still other embodiments, NAND flash memory NFMEM1 and NAND flash memory NFMEM2 are controlled according to the CE signal, as illustrated in FIGS. 4 through 7A. In some embodiments, at least one of the receiver and driver of NAND flash memory NFMEM3 may be always turned on regardless of the CE signal. The number of NAND flash memories in FIG. 12 is merely an example, and the inventive concept is not limited to this number.

FIG. 13 illustrates NAND flash memory system 100 according to another embodiment of the inventive concept.

Referring to FIG. 13, NAND flash memory system 100 comprises controller CTRL and NAND flash memory NFMEM. Controller CTRL comprises a processor PROS, a random access memory (RAM), a cache buffer (CBUF), and a memory controller Ctrl, which are connected to each other via a bus BUS. Processor PROS controls NAND flash memory system 100 so that memory controller Ctrl receives and/or transmits data from and/or to NAND flash memory NFMEM in response to a request (command, address, data) of a host. Processor PROS and memory controller Ctrl of NAND flash memory system 100 illustrated in FIG. 13 may be also implemented as one ARM processor. Data required in an operation of processor PROS may be loaded on the RAM.

A host interface HOST I/F receives the request from the host and transmits the received request to processor PROS or transmits the data transmitted from NAND flash memory NFMEM to the host. Host interface HOST I/F may use one of various interface protocols to communicate with the host, such as Universal Serial Bus (USB), Man Machine Communication (MMC), Peripheral Component Interconnect-Express (PCI-E), Serial Advanced Technology Attachment (SATA), Parallel Advanced Technology Attachment (PATA), Small Computer System Interface (SCSI), Enhanced Small Device Interface (ESDI), or Intelligent Drive Electronics (IDE). The data to be transmitted to NAND flash memory NFMEM or that is transmitted from NAND flash memory NFMEM may be temporarily stored in cache buffer CBUF. Cache buffer CBUF may be an SRAM, for example.

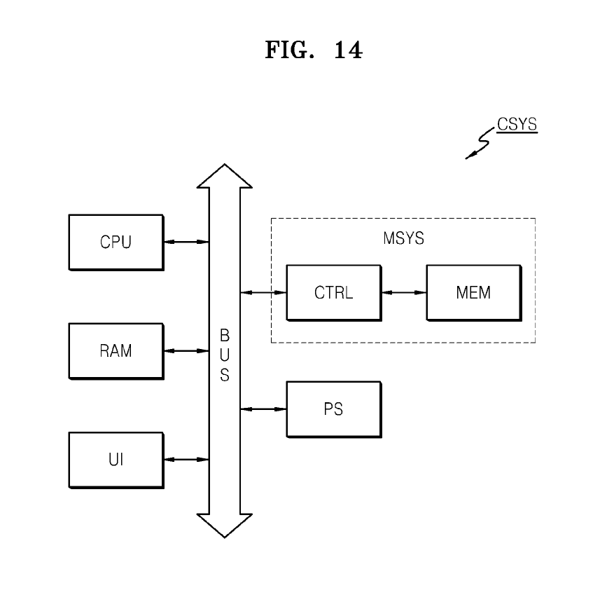

FIG. 14 is a block diagram of a computing system CSYS according to an embodiment of the inventive concept.

Referring to FIG. 14, computing system CSYS comprises a processor CPU, a system memory RAM, and a semiconductor memory system MSYS, which are electrically connected to each other by a bus BUS. Semiconductor memory system MSYS comprises a memory controller CTRL and a semiconductor memory device MEM. N-bit data (N≧1) that is processed or to be processed by the processor CPU may be stored in semiconductor memory device MEM. Semiconductor memory system MSYS of FIG. 14 may be NAND flash memory system 100 of FIG. 1 or 12. In addition, computing system CSYS of FIG. 14 may further comprise a user interface (UI) and a power supply device (PS), which are electrically connected to bus BUS.

Where computing system CSYS of FIG. 14 is a mobile device, it may further comprise a battery for supplying an operational voltage of computing system CSYS and a modem, such as a baseband chipset. In addition, computing system CSYS of FIG. 14 may further comprise an application chipset, a Camera Image Processor (CIS), a mobile DRAM, or other additional features.

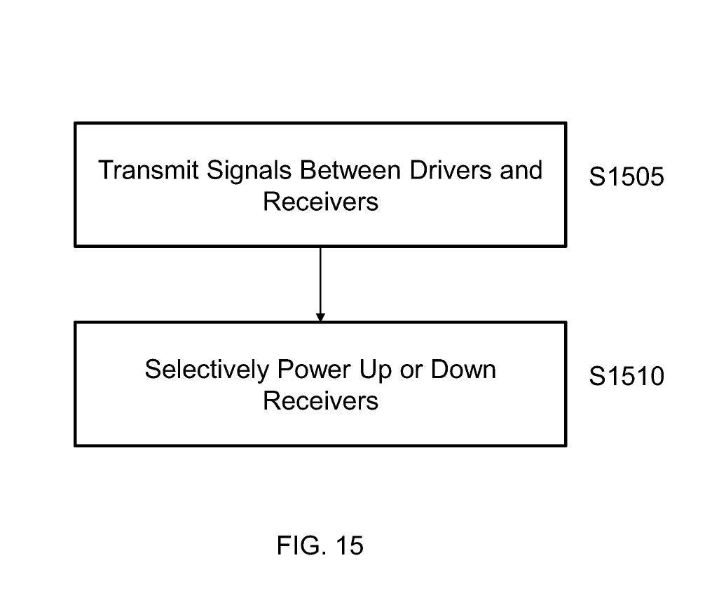

FIG. 15 is a flowchart illustrating a method of operating a NAND flash memory according to an embodiment of the inventive concept. This method can be performed, for instance, in memory system 100 of FIG. 1 or FIG. 13. In the description that follows, example method steps will be indicated by parentheses.

Referring to FIG. 15, the method comprises transmitting signals between a plurality of drivers in pads of a controller to a plurality of corresponding receivers in pads of a NAND flash memory device (S1505). This transmission can be performed between drivers and receivers such as those illustrated in FIGS. 1 to 11, for example. The method further comprises selectively powering up or down a plurality of the receivers in response to a logic level of a first signal applied to one of the receivers (S1510). This can be accomplished, for instance, as shown in FIGS. 4, 8, and 10 through the use of a chip enable signal.

In some embodiments, the method may further comprise selectively powering up or down a plurality of the drivers in response to the logic level of the first signal applied to the one of the receivers, as illustrated in FIG. 8, for example. Moreover, as described above, the plurality of receivers can be selectively powered down as a consequence of their completing reception of the signals. The determination of whether reception has been completed can be performed based on timer, a counter, or a voltage level of a capacitor, as described in relation to FIGS. 6 and 7, for example.

While the inventive concept has been particularly shown and described with reference to various embodiments, it will be understood by those of ordinary skill in the art that various changes in form and details may be made therein without departing from the scope of the inventive concept as defined by the claims. For example, although certain embodiments relate to a NAND flash memory system, the described concepts can be applied to other types of memories, such as RAM, read only memory (ROM), dynamic random access memory (DRAM), synchronous dynamic random access memory (SDRAM), and NOR flash memory.

What is claimed is:

1. A NAND flash memory device comprising:
a NAND flash memory comprising:
a first pad comprising a first receiver configured to receive a first signal; and
a plurality of second pads comprising a plurality of respective second receivers configured to receive a plurality of respective second signals;
wherein the second receivers are selectively powered according to a logic level of the first signal.

2. The NAND flash memory device of claim 1, wherein power is not supplied to the second receivers where the first signal is at a first logic level, and power is supplied to the second receivers where the first signal is at a second logic level.

3. The NAND flash memory device of claim 1, wherein the first signal is a chip enable signal.

4. The NAND flash memory device of claim 3, wherein the NAND flash memory is powered up as a consequence of the first receiver receiving the chip enable signal.

5. The NAND flash memory device of claim 1, wherein the second signals comprise at least one of an address enable signal, a common enable signal, a ready/busy signal, a read enable signal, a write enable signal, a write protect signal, and a data signal.

6. The NAND flash memory device of claim 1, wherein the second receivers are turned off in response to completing reception of the second signals.

7. The NAND flash memory device of claim 6, wherein the NAND flash memory is powered down in response to the second receivers being turned off.

8. A NAND flash memory system, comprising:
a NAND flash memory comprising a plurality of first pads; and
a controller configured to control the NAND flash memory and comprising a plurality of second pads,
wherein each of the first pads comprises a receiver, and each of the plurality of second pads comprises a driver, and
each receiver receives one signal among a first signal and a plurality of second signals, and
each driver transmits one signal among the first signal and the plurality of second signals, and
power of receivers that receive the second signals and power of drivers that transmit the second signals are controlled in response to the first signal.

9. The NAND flash memory system of claim 8, wherein, where the first signal is at a first logic level, power of the receivers that receive the second signals and power of the drivers that transmit the second signals are turned off, and in response to the first signal transitioning from the first logic level to a second logic level, power of the receivers that receive the second signals and power of the drivers that transmit the second signal are turned on.

10. The NAND flash memory system of claim 8, wherein the first signal is a chip enable signal.

11. The NAND flash memory system of claim 10, wherein, where the chip enable signal is received from the receiver that receives the first signal, power of the NAND flash memory is powered up.

12. The NAND flash memory system of claim 8, wherein the second signals comprise at least one signal among an address enable signal, a common enable signal, a ready/busy signal, a read enable signal, a write enable signal, a write protect signal, and a data signal.

13. The NAND flash memory system of claim 8, wherein the receivers that receive the second signals and the drivers that transmit the second signals are turned off as a consequence of the receivers completing reception of the second signals.

14. The NAND flash memory system of claim 13, wherein the controller determines through a timer or a counter whether the receivers have completed reception of the second signals.

15. The NAND flash memory system of claim 13, wherein the controller determines whether the receivers have completed reception of the second signals based on a voltage level of a capacitor connected to the receivers that receive the second signals.

16. A method of operating a NAND flash memory system, comprising:
transmitting signals between a plurality of drivers in pads of a controller to a plurality of corresponding receivers in pads of a NAND flash memory device; and
selectively powering up or down a plurality of the receivers in response to a logic level of a first signal applied to one of the receivers.

17. The method of claim 16, further comprising:
selectively powering up or down a plurality of the drivers in response to the logic level of the first signal applied to the one of the receivers.

18. The method of claim 16, wherein the first signal is a chip enable signal.

19. The method of claim 16, further comprising selectively powering down the plurality of receivers as a consequence of the receivers completing reception of the signals.

20. The method of claim 19, further comprising determining whether the receivers have completed reception of the signals according to a timer, a counter, or a voltage level of a capacitor.
